(19) United States
(12) Patent Application Publication
(10) Pub. No.: US 2011/0006771 A1
(43) Pub. Date: Jan. 13, 2011

(54) MAGNETIC RESONANCE APPARATUS AND METHOD

(75) Inventors: Christopher Paul Randell, Wotton-under-Edge (GB); Andrew Mark Woolfrey, Wotton-under-Edge (GB)

Correspondence Address: OLIFF & BERRIDGE, PLC, P.O. BOX 320850, ALEXANDRIA, VA, 22320-4850, US

(73) Assignees: RENISHAW PLC, WOTTON-UNDER-EDGE (GB); PULSETEQ LIMITED, WOTTON-UNDER-EDGE (GB)

(21) Appl. No.: 12/864,733

(22) PCT Filed: Feb. 3, 2009
(86) PCT No.: PCT/GB09/00287

§ 371 Date: Jul. 27, 2010

(30) Foreign Application Priority Data
Feb. 4, 2008 (GB) 0802001.8

(51) Int. Cl. G01R 33/44

(52) U.S. Cl. 324/318

(57) ABSTRACT

Magnetic resonance apparatus, e.g. for magnetic resonance imaging, is described that includes a cooler unit and one or more radio-frequency (RF) coil assemblies. A separable thermal connection is provided between the cooler unit and the one or more RF coil assemblies. This separable thermal connection allows the one or more RF coil assemblies to be detached from the cooler unit after the one or more coil assemblies have been cooled to the required operating temperature. Each RF coil assembly can then be used for magnetic resonance imaging or the like. A plurality of different RF coil assemblies may thus be cooled by a single cooler unit.

The present invention relates to magnet resonance apparatus and in particular to magnetic resonance apparatus comprising cooled radiofrequency (RF) coils.

Magnetic resonance imaging (MRI) is a well known imaging technique that is widely used in the medical field for diagnostic purposes. An MRI scanner typically comprises an electromagnet in which a subject (e.g. a person or animal) is placed. The spin of atomic nuclei (e.g. in the tissue of a patient being scanned) produce magnetic moments that align with the static magnetic field generated by the electromagnet. One or more RF transmit coils are provided to transmit RF pulses to perturb the spin alignment of the nuclei and one or more RF receive coils are provided for monitoring the effect of the perturbation in order to extract magnetic resonance (MR) information. It is also known to locate such transmit and/or receive coils in the vicinity of specific parts of the body (e.g. placed against the head, chest, knees etc) to provide an enhanced image of that region.

It has been proposed previously to cool receive coils formed from normal (e.g. metallic) conductors and to use high temperature superconductors (HTSC) based coils which necessarily require cooling in order to improve the signal to noise ratio. U.S. Pat. No. 5,508,613, for example, describes a cooling technique in which a cryogenic fluid is pumped along a transfer tube to a heat exchanger which, in turn, cools a receive coil formed on a substrate. U.S. Pat. No. 7,003,963 is another example of a cooled coil system in which a thermally conducting ceramic material is used, instead of a cryogenically cooled fluid, to provide a thermal link between the cold head of a refrigeration unit and a receive coil.

Although cooled coils provide an improved signal to noise ratio, the widespread cooling of RF coils has been hindered by the many practical difficulties and patient safety issues that are associated with cooling coils during MRI scanning. In a system cooled by a cryogenic fluid, for example, the coolant transfer tube must be sufficiently long to enable the refrigeration unit to be placed away from the magnetic field of the scanner or a non-magnetic refrigeration unit is required. Handling the tubing of such a system when placing a patient in the scanner can also be awkward for operators. Furthermore, circulating cryogenic coolant through a coil in close proximity to a patient can increase the difficulty of gaining regulatory approval for the coil apparatus because serious burn injuries could occur if the tube was to rupture or a seal was to fail during use.

According to a first aspect of the invention, magnetic resonance apparatus comprises a cooler unit and one or more radiofrequency (RF) coil assemblies, characterised in that a separable thermal connection is provided between the cooler unit and the one or more RF coil assemblies.

The present invention thus provides apparatus, for use in magnetic resonance imaging (MRI), magnetic resonance spectroscopy (MRS) or the like, that comprises at least one RF coil assembly that can be releasably attached to a cooler unit. Each RF coil assembly advantageously comprises one or more RF coils that may be supported on a substrate. The present invention thus allows, for example, the RF coil assembly to be cooled to the required operating temperature and then demounted from the cooler unit for use in MR apparatus. The RF coil assembly may then be remounted to the cooler unit when further cooling is required.

The present invention thus has several advantages over prior art techniques in which the coil assembly is permanently attached to the cooling source. In particular, there is no need to maintain a thermal connection with a cooler unit (e.g. via coolant pipes or the like) whilst the coil assembly is being used in magnetic resonance (e.g. MRI or MRS) apparatus thereby increasing the flexibility and ease of RF coil assembly placement and use. The present invention also overcomes potential safety issues associated with circulating cryogenic coolant in coil assemblies placed in proximity to a patient's skin.

Advantageously, the separable thermal connection can be broken, thereby allowing the one or more RF coil assemblies to be detached from the cooler unit, when the one or more coil assemblies have been cooled to the required operating temperature. In other words, the separable thermal connection allows a RF coil assembly to be detached from the cooler unit even when the RF coil assembly is cooled to the desired operating temperature.

Preferably, the apparatus comprises a plurality of RF coil assemblies. For example, at least two, at least three or at least four RF coil assemblies may be provided. A separable thermal connection may be establishable between the cooler unit and only one of the one or more RF coil assemblies at any one time. In other words, apparatus may be provided in which only one RF coil assembly may be cooled at a time.

Advantageously, a plurality of separable thermal connections can be simultaneously established between the cooler unit and a plurality of RF coil assemblies. In this manner, a plurality of RF coil assemblies may be cooled in parallel and any one of these RF coil assemblies may be demounted for use as required. In such an arrangement, the cooler unit may be provided in the form of a rack for retaining the plurality of RF coil assemblies.

A variety of types of separable thermal connection between the cooler unit and the one or more RF coil assemblies may be provided. For example, cryogenic fluid or solid material based connections may be used. Advantageously, the separable thermal connection between the cooler unit and the one or more RF coil assemblies comprises at least one conduit carrying a cooled fluid. Advantageously, each of the one or more RF coil assemblies comprise a heat exchanger that allows heat to be transferred from the one or more RF coil assemblies into the cooled fluid. Conveniently, the separable thermal connection between the cooler unit and the one or more RF coil assemblies comprises one or more portions of solid, thermally conductive, material. Suitable solid, thermally conductive, materials are described in U.S. Pat. No. 7,003,963.

In a preferred embodiment, the cooler unit comprises at least one first thermal connector portion. One or more RF coil assemblies that each comprise a second thermal connector portion may also be provided. A first thermal connector portion of the cooler unit can then be releasably attached to a second thermal connector portion of an RF coil assembly thereby establishing the separable thermal connection between the cooler unit and the RF coil assembly. The first and second thermal connector portions conveniently define, when mated, at least one conduit for cooled fluid through the thermal connector. Advantageously, the first and second thermal connector portions comprise complimentary portions of thermally conductive, solid, material that, when mated, provide a thermal pathway through the thermal connector. An evacuated connector enclosure may also be provided for housing the first thermal connector portion when connected to a second thermal connector portion; e.g. to reduce thermal losses from the connector

Advantageously, the one or more RF coil assemblies comprise a thermal mass and at least one RF coil. The at least one RF coil is preferably in thermal contact with the thermal mass. For a given amount of thermal loss, the properties of the thermal, or cold, mass will determine how long the RF coil can be kept at the required operating temperature. A thermal mass is conveniently selected that is within a certain volume limit, has a total mass lower than a certain limit, meets a minimum heat sink requirement per Kelvin and provides a certain minimum thermal diffusivity to ensure sufficient heat is transported away from the at least one RF coil.

The thermal mass advantageously comprises a metal (e.g. Lead, Zinc etc) because many metals have a significant heat capacity (e.g. within the range of 0.1 to 0.3 j/gK) at 60K. Preferably, the thermal mass comprises Lead. The use of Lead is preferred, although by no means essential, for temperatures down to approximately 8K as it combines a significant heat capacity with a high density. A solid block of metal may be provided. Advantageously, the metal is structured (e.g. provided with fins) to reduce the generation of Eddy currents. If cooling to below 8K is required, rare earth nitrides (e.g. ErN) that exhibit a phase change can advantageously be used. Furthermore, other materials may be considered if operating near a phase transition temperature; for example, the latent heat of fusion of nitrogen at 63K may be employed. Metal compounds, such as oxides (e.g. Alumina), may also be conveniently used. The thermal mass may be provided by solid material, a gel or a liquid. For example, solid nitrogen may be used. It should be re-emphasised that the above mentioned materials should not be seen as limiting and the skilled person would appreciate the numerous other materials that could be employed to provide the thermal mass.

To reduce thermal losses after the RF coil assembly is demounted from the cooler unit, one or more of the RF coil assemblies preferably comprise thermal insulation. Advantageously, the at least one RF coil of each coil assembly is substantially thermally insulated from the surrounding environment by the thermal insulation. Advantageously, the thermal insulation comprises a vacuum; e.g. a vacuum of less than 10⁻³ mBar may be provided. Conveniently, one or more of the RF coil assemblies comprise at least one RF coil and an outer housing that defines a sealed chamber in which a vacuum can be maintain, the at least one RF coil of the coil assembly being located in the sealed chamber. The thermal insulation may conveniently comprise a thermally insulating foam (e.g. formed from a plastic, polystyrene etc). Conveniently, an inner vacuum region may be combined with an outer thermally insulating foam. For example, the sealed vacuum chamber may be surrounded by an outer layer of insulating material. In this manner, thermal losses are further reduced. Any suitable combination of a vacuum and/or insulating material may thus be provided.

Preferably, the one or more RF coil assemblies are configured to stay below an operating temperature limit for at least 10 minutes after thermal separation from the cooler unit. More preferably, the RF coil assemblies are configured to stay below the operating temperature limit for at least 15 minutes, more preferably for at least 20 minutes, more preferably for at least 25 minutes, more preferably for at least 30 minutes and more preferably for at least 45 minutes. The operating temperature limit will depend on the material from which the RF coils are formed. For high temperature superconducting material an upper limit of, say, 80K may be set. For normal conductor, cooling to 20K or below may be required. A skilled person would appreciate how the balance between the heat capacity provided by RF coil assembly and the thermal insulation of such an assembly can be selected to provide the required operating time.

The apparatus of the present invention may comprise any type of cooler unit. For example, a Stirling cycle cooler, a pulse tube cooler or a liquid nitrogen based cooler may be provided. Single-stage and two-stage Gifford-MacMahon coolers may also be used for cooling to 80K and 10 k respectively. Conveniently, the cooler unit comprises a cold head, wherein the separable thermal connection is provided between the cold head and the one or more coil assemblies. As noted above, the present invention means that the cooler need not be located in proximity to the MR apparatus and may thus include magnetisable elements.

Advantageously, the one or more RF coil assemblies comprise at least one RF receive coil. Conveniently, the one or more RF coil assemblies comprise at least one RF transmit coil. In other words, transmit, receive or transmit/receive RF coils may be provided in the coil assemblies. Conveniently, the one or more RF coil assemblies comprise at least one RF coil tuned to the excitation frequency of Hydrogen, Helium-3, Carbon-13, Sodium, Fluorine or Phosphorous nuclei. It should also be noted that a plurality of RF coil assemblies could be provided that include different types, number or arrangements of RF coils. The one or more RF coil assemblies may also comprise RF coil tuning electronics; e.g. tuning capacitors or the like.

According to a second aspect of the invention, an RF coil module or assembly for use with magnetic resonance apparatus is provided. The RF coil module comprises at least one RF coil and is characterised in that the RF coil module comprises the first part of a separable thermal connector that is releasably connectable to the second part of a separable thermal connector provided on an associated cooler unit. Advantageously, the RF coil module comprises a thermal mass, the thermal mass being in thermal contact with the at least one RF coil. Further preferred features of the RF coil module are outlined above.

According to a third aspect of the invention, a cooler unit comprises a cooling source and at least one second part of a separable thermal connector, wherein the at least one second part of the separable thermal connector is releasably connectable to the first part of the thermal connector provided on a RF coil module. Advantageously, the first part of the thermal connector provided on a RF coil module is in accordance with the second aspect of the invention described above.

According to a fourth aspect of the invention, a method of cooling RF coil assemblies comprises the steps of (i) taking one or more RF coil assemblies that each comprise at least one RF coil, (ii) placing the one or more RF coil assemblies in thermal contact with a cooler unit to cool the RF coil assemblies, characterised by (iii) separating the one or more cooled RF coil assemblies from the cooler unit prior to use with magnetic resonance apparatus.

According to a further aspect of the invention, magnetic resonance apparatus comprises a cooler unit and a plurality of radiofrequency (RF) coil assemblies, wherein thermal connections can be simultaneously provided between the cooler unit and each of the plurality of coil assemblies.

The invention will now be described, by way of example only, with reference to the accompanying drawings in which;

FIG. 1 shows a prior art cooled RF coil arrangement,

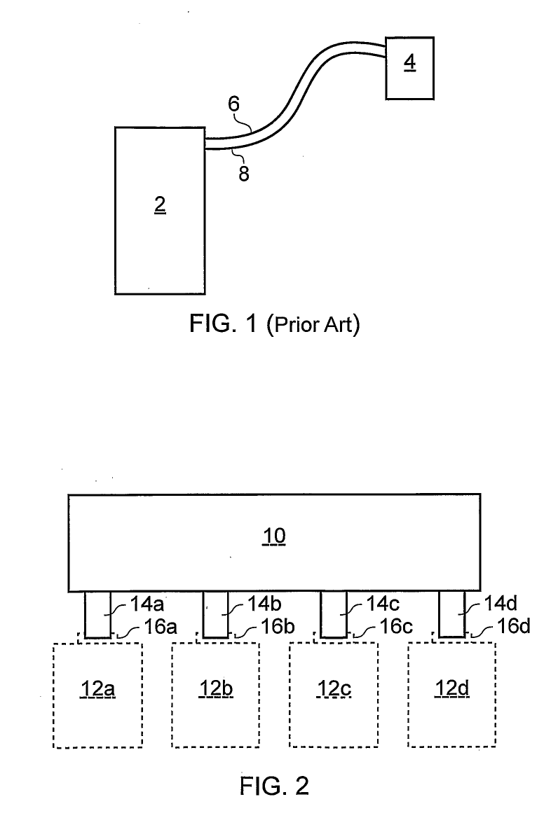

FIG. 2 schematically illustrates a modular RF coil and cooler unit arrangement of the present invention,

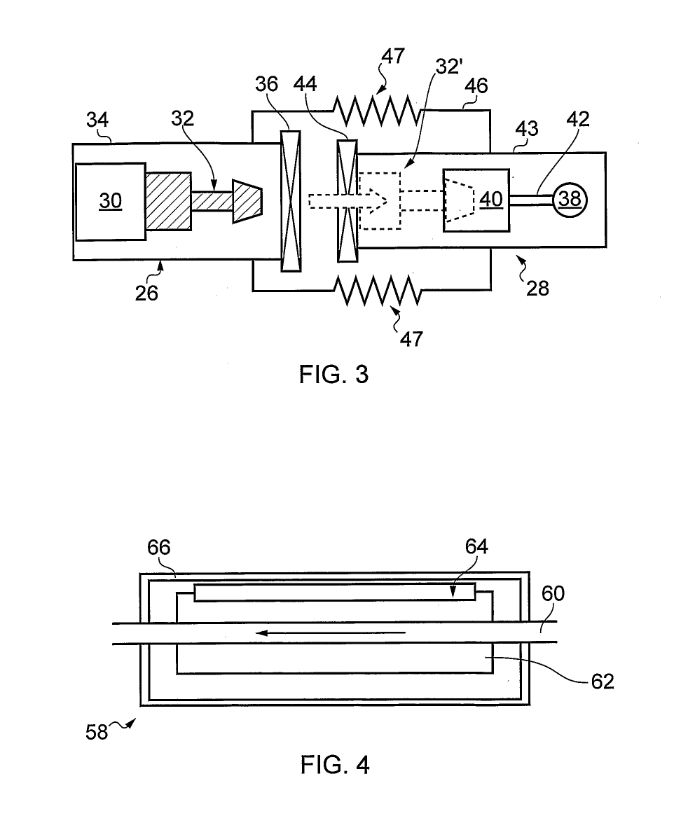

FIG. 3 illustrates a first thermal linkage between a coil assembly and a cooler unit,

FIG. 4 illustrates a coil assembly cooled by a flow of liquid nitrogen,

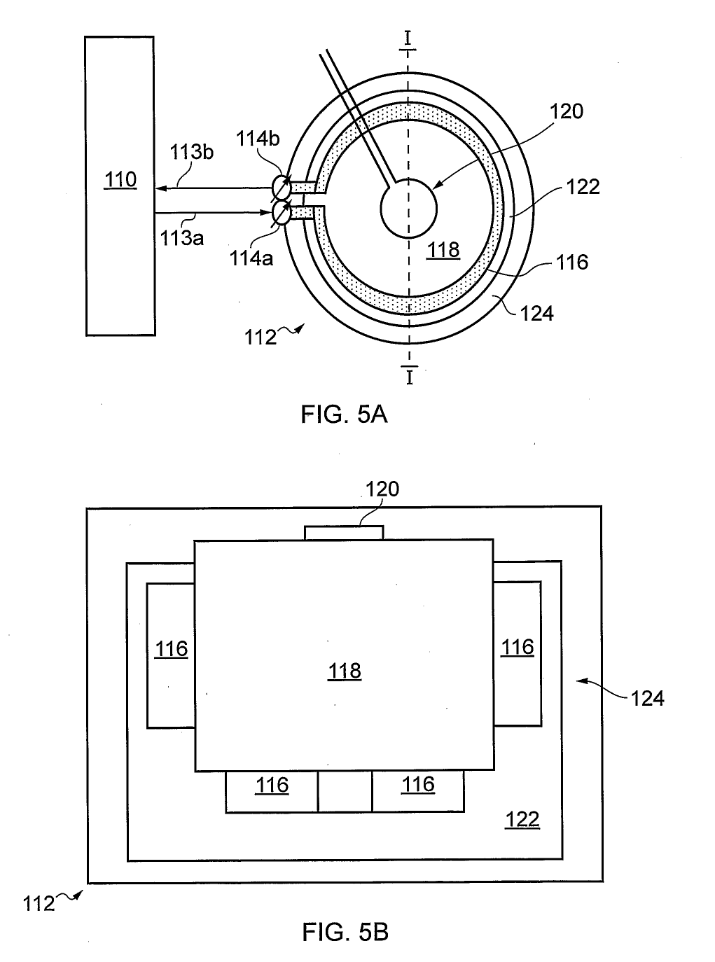

FIGS. 5A and 5B illustrate a further embodiment of the present invention that is cooled using a flow of liquid nitrogen,

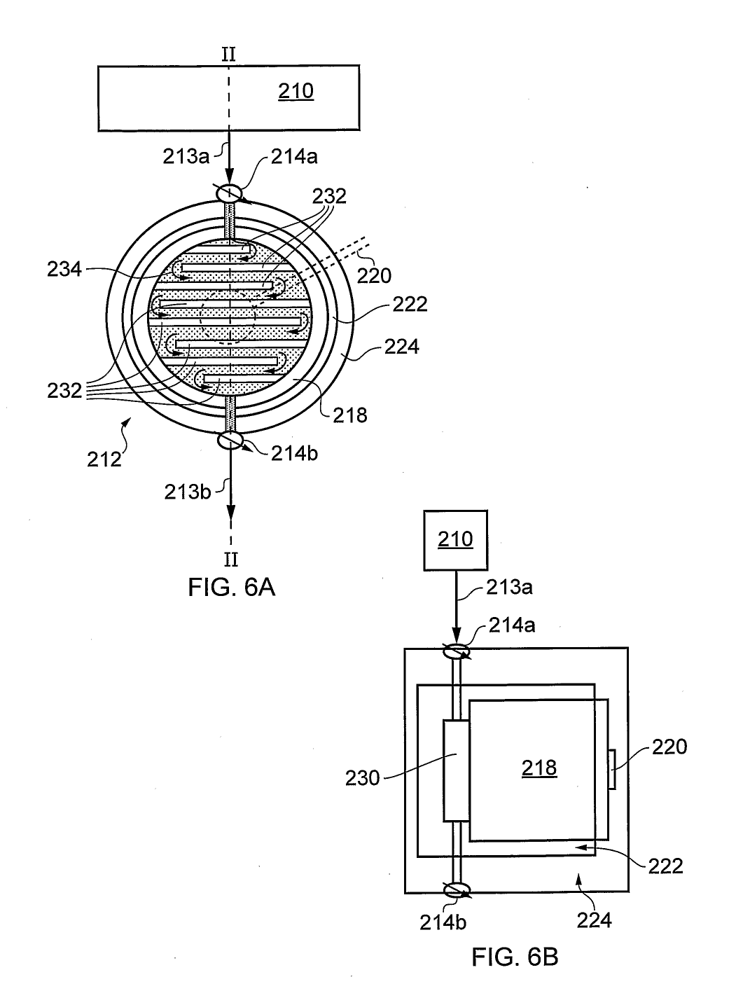

FIGS. 6A and 6B illustrate a yet further embodiment of the present invention,

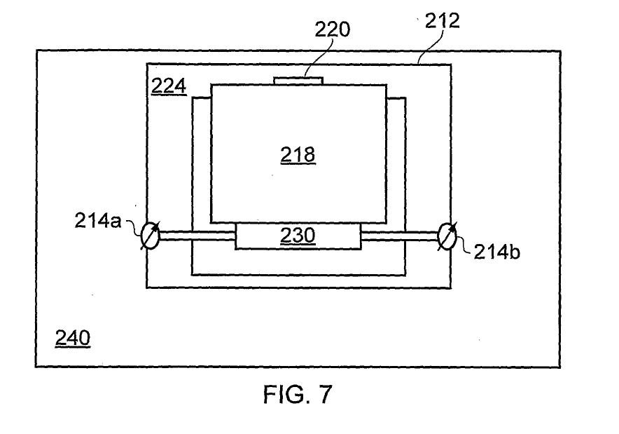

FIG. 7 illustrates the RF coil assembly of FIGS. 6A and 6B cooled for use, and

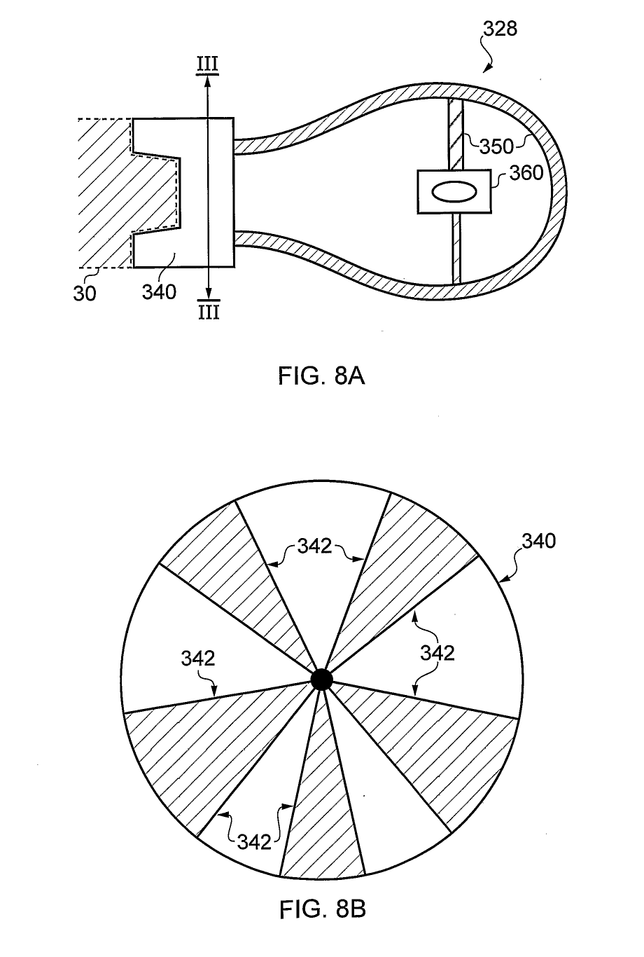

FIGS. 8A and 8B show an alternative cold mass for apparatus of the type shown in FIG. 3.

Referring to FIG. 1, a illustrative example of a prior art cooled RF coil assembly is illustrated.

The apparatus comprises a cooler unit 2, such as Stirling cycle cooler, having a cold head that cools a cryogenic fluid. An RF coil assembly 4 is provided that includes an RF coil. The RF coil assembly is permanently connected to the cooler unit by a pair of fluid transmission lines 6 and 8. Cooled fluid is passed from the cooler unit to the RF coil assembly 4 via one transmission line 6 and this fluid is returned to the cooler unit for re-cooling via the other transmission line 8. The RF coil assembly 4, still attached to the cooler unit 2 by the fluid transmission lines 6 and 8, is then placed in the required location in the magnetic resonance apparatus. Magnetic resonance images or spectra are then acquired using the RF coil of the coil assembly 4.

It can be seen that the need to maintain the circulation of cooling fluid in such a prior art system makes the practical use of such apparatus cumbersome and awkward. Furthermore, it can prove difficult and expensive to ensure that none of the apparatus within the magnetic field of the MR scanner is magnetisable and any leakage of the cooled fluid could cause serious injury to the subject. For these and various other reasons, cooled coils are not widely used at present for medical imaging purposes.

Referring to FIG. 2, modular or demountable apparatus of the present invention is illustrated.

The modular apparatus comprises a cooler unit 10 and multiple, detachable or demountable, RF coil assemblies or modules 12a-12d (hereinafter collectively referred to as RF coil assemblies 12). In particular, the cooler unit 10 comprises four first thermal connector portions 14a-14d that are in thermal contact with the cold head of the cooler unit 10. Each of the RF coil assemblies 12a-12d comprise a second thermal connector portion 16a-16d. The first and second thermal connector portions, when connected, form a thermal connection that provides a thermally conductive link between the relevant RF coil assembly and the cooler unit. This permits the RF coil assemblies 12 (and in particular the RF coils contained in such assemblies) to be cooled when they are attached to the cooler unit 10. When it is wished to use one of the RF coil assemblies 12 for MRI purposes, the required coil assembly is detached or demounted from the cooler unit and placed at the desired location within the MRI apparatus. For example, the RF coil assembly may be placed against a part of the body (e.g. the neck, head, chest etc) of a patient. The RF coil assemblies 12 can thus be used in MRI apparatus without the need for a trailing coolant supply tube or the like to maintain a thermal link with a cooler unit.

It should also be noted that any number of RF coil assemblies could be mounted to the cooler unit; the example of providing four such connections should in no way be seen as limiting. The RF coil assemblies 12 shown in FIG. 2 are identical, but this is unnecessary and different types or configuration of RF coils assemblies may be provided. As described in more detail below, the design of the RF coil assembly will dictate the length of time that it can be used for after being demounted from the cooler unit; a thermal mass and/or insulation may thus be provided to increase the amount of usage time after disconnection. Details are also given below of the various thermal connectors, e.g. fluidic connectors or solid thermal connections, that can be used to implement the invention.

Referring now to FIG. 3, a first example of how a separable thermal connection can be established between a cooler unit 26 and a RF coil assembly 28 is illustrated.

The cooler unit 26 comprises a cold head 30 in thermal contact with a protruding feature 32 formed from a thermally conductive solid material, such as a metal or ceramic. The cold head 30 and feature 32 are contained within a first evacuated enclosure 34 and are accessible by a first vacuum gate valve 36. The RF coil assembly 28 comprises a second evacuated enclosure 43 housing a RF coil 38 attached to a cold mass 40 by a cold finger 42. The cold mass 40 is accessible via a second vacuum gate valve 44.

The RF coil assembly 28 and cooler unit 26 are arranged so that, when the first vacuum gate valve 36 and the second vacuum gate valve 44 are opened, the thermally conductive feature 32 of the cooler unit 26 can be brought into thermal contact with the cold mass 40 of the RF coil assembly 28; this is shown as dotted outline 32′. A thermal path from the cold head 30 to the cold mass 40 is provided thereby allowing the cold mass to be cooled. In this arrangement, the need for circulation of a cooled liquid is avoided. A third, outer, evacuated enclosure 46 is also provided to maintain the vacuum in the first and second evacuated enclosures 34 and 43 during connection. The evacuated enclosure 46 comprises a bellowed section 47 to allow a vacuum to be maintained during attachment and disengagement of the RF coil assembly 28 and cooler unit 26.

Referring to FIG. 4, a liquid nitrogen cooled RF coil assembly 58 is shown. A liquid nitrogen cooling pipe 60 is passed through a cold mass 62. The cold mass 62 is in thermal contact with a Sapphire substrate 64 that carries an RF coil. An insulated, sealed, enclosure 66 may be provided and a vacuum may be provided within the enclosure 66. This vacuum may be refreshed whenever the coil assembly is being cooled or a permanent vacuum connection may be established. A vacuum seal, such as an O-ring (e.g. a compression or piston seal O-ring), may provide access to the vacuum.

In use, a supply of liquid nitrogen is firstly passed through the cooling pipe 60 to cool the cold mass 62. After cooling the cold mass 62 to the desired temperature, the liquid nitrogen supply is disconnected from the cooling pipe 60 whenever the RF coil assembly 58 is required for imaging purposes. A variety of suitable liquid nitrogen connectors are already known in the cryogenic art; for example, a two stage seal may be provided having a PTFE seal at the cold end backed up by an O-ring seal at room temperature. Such a connector is preferably arranged to include self-sealing couplings to avoid the possibility of the operator or patient coming into contact with a cooled surface or liquid nitrogen.

Once disconnected from the liquid nitrogen supply, any liquid nitrogen remaining in the cooling pipe 60 may then be drained. This arrangement minimizes safety issues associated with the subject being close to liquid nitrogen and avoids needing to deal with boil-off while the coil is in the MRI scanner. Alternatively, a store of liquid nitrogen may be retained within the coil assembly and near room temperature nitrogen gas may be vented to the atmosphere during use.

Referring to FIGS. 5A and 5B, a further embodiment of modular apparatus of the present invention is illustrated. In particular, FIG. 5A shows a plan view of a cooler unit 110 and a demountable RF coil assembly 112 and FIG. 5B shows a sectional view of the same apparatus along the line I-I of FIG. 5A.

The cooler unit 110 comprises a controlled liquid nitrogen supply from a dewar. The liquid nitrogen is passed (e.g. pumped) along supply lines 113a and 113b to the associated demountable RF coil assembly 112 via a pair of releasable bayonet valves 114a and 114b. In particular, liquid nitrogen can be pumped into the RF coil assembly 112 via the first bayonet release valve 114a and liquid is returned via the second bayonet release valve 114b. The bayonet release valves are operable at liquid nitrogen temperatures; i.e. the valves can be opened/closed and connected/disconnected to supply tubes when cooled to the operating temperature.

The RF coil assembly 112 comprises a fluidic passageway 116 that surrounds an alumina block 118. Although the fluidic passageway 116 is shown as passing around the sides and underneath the alumina block 118, the skilled person would appreciate that any suitable fluidic path around and/or through the block 118 could be provided. A substrate 120 carrying an RF coil is mounted on the alumina block 118. Super-insulation 122 surrounds the Alumina block 118 and the fluidic passageway 116 and the whole arrangement is located inside a vacuum enclosure 124. In use, the bayonet release valves 114a and 114b of the demountable RF coil assembly 112 are connected to the liquid nitrogen supply and return lines 113a and 113b of the cooler unit 110. Liquid nitrogen is then circulated around the fluidic passageway 116 of the RF coil assembly 112 thereby cooling the Alumina block 118 to cryogenic temperatures. Once cooled, all or some of the liquid nitrogen can be drained from the RF coil assembly 112 and the valves 114a and 114b closed. The supply tubes 113a and 113b can then be detached from the bayonet release valves 114a and 114b. The thermal mass of the alumina block 118 ensures the substrate 120 that carries the RF coil is kept cool during subsequent use of the RF coil assembly 112.

Referring to FIGS. 6A and 6B, a gravity fed embodiment of modular apparatus of the present invention is illustrated. In particular, FIG. 6A shows a plan view of a cooler unit 210 and a demountable RF coil assembly 212 and FIG. 6B shows a sectional view of the same apparatus along the line II-II of FIG. 6A.

The cooler unit 210 comprises a controlled liquid nitrogen supply and includes an outlet supply pipe 213a that is releasably connectable to the bayonet release valve 214a of the demountable RF coil assembly 212.

The RF coil assembly 212 comprises a base 230 through which liquid nitrogen flows when passing from an inlet bayonet release valve 214a to an outlet bayonet release valve 214b. The bayonet release valves 214a and 214b may be similar to those described with reference to FIGS. 5A and 5b above. The base 230 comprises a series of interdigitated fins 232 that define a fluid pathway as indicated by arrows 234. The base 230 is mounted to an alumina block 218 on which a substrate 220 that carries the RF coil is also mounted. Super-insulation 222 surrounds the Alumina block 218 and the whole arrangement is located inside a vacuum enclosure 224.

To cool the RF coil assembly 212, liquid nitrogen from the cooler unit 210 is gravity fed into the top of the fluid channel of the base 230 via the inlet bayonet release valve 214a. The liquid nitrogen exits the base via the outlet bayonet release valve 214b and, although not shown, may be returned to the cooler unit 210 if required. In this manner the Alumina block 218 is cooled to cryogenic temperatures by the liquid nitrogen. Once cooled, the (uppermost) inlet bayonet release valve 214a may be closed and some or all of the remaining liquid nitrogen drained from the (lower) outlet bayonet release valve 214b.

Referring to FIG. 7, the cooled RF coil assembly 212 may then be placed in an insulating blanket 240 to maintain the necessary cooling for as long as possible. The cooled RF coil assembly 212 may then be used for MRI imaging etc.

Referring to FIG. 8A, an RF coil assembly 328 is shown that is a variant of the RF coil assembly 28 described above with reference to FIG. 3. The RF coil assembly 328 comprises a cold mass 340 formed from a metal that is suitable for engaging the cold head 30 of a cooler unit. A conductive cooling track 350 is provided that acts as an RF shield and also places the cold mass 340 into thermal contact with a substrate 360 carrying the RF coil. Although not shown, appropriate insulation (e.g. a vacuum and/or insulating material) may be provided.

Referring to FIG. 8B, the structure of the cold mass 340 along line of FIG. 8A is shown. In particular, the cold mass 340 is not a solid block of metal but instead comprises a plurality of radially extending fins 342. The arrangement of fins has the effect of maximising the mass of metal that can be provided before circular paths are present in which Eddy currents can be induced by the magnetic field gradient.

It should also be remembered that the above described embodiments are provided as examples only and that the skilled person would appreciate the numerous alternative configurations and arrangements that could be used to implement the present invention.

1. Magnetic resonance apparatus comprising
a cooler unit,
one or more radiofrequency (RF) coil assemblies, and
a separable thermal connection provided between the cooler unit and the one or more RF coil assemblies.

2. An apparatus according to claim 1, wherein the separable thermal connection can be broken, thereby allowing the one or more RF coil assemblies to be detached from the cooler unit, when the one or more coil assemblies have been cooled to the required operating temperature.

3. An apparatus according to claim 1, comprising a plurality of RF coil assemblies.

4. An apparatus according to claim 1, wherein, at any one time, a separable thermal connection can be established between the cooler unit and only one of the one or more RF coil assemblies.

5. An apparatus according to claim 1, wherein a plurality of separable thermal connections can be simultaneously established between the cooler unit and a plurality of RF coil assemblies.

6. An apparatus according to claim 1, wherein the separable thermal connection between the cooler unit and the one or more RF coil assemblies comprises at least one conduit carrying a cooled fluid.

7. An apparatus according to claim 1, wherein the separable thermal connection between the cooler unit and the one or more RF coil assemblies comprises one or more portions of solid, thermally conductive, material.

8. Apparatus according to claim 1, wherein the cooler unit comprises at least one first thermal connector portion and one or more RF coil assemblies are provided that each comprise a second thermal connector portion, wherein a first thermal connector portion of the cooler unit can be releasably attached to a second thermal connector portion of an RF coil assembly thereby establishing the separable thermal connection between the cooler unit and the RF coil assembly.

9. An apparatus according to claim 8, wherein the first and second thermal connector portions define, when mated, at least one conduit for cooled fluid through the thermal connector.

10. An apparatus according to claim 8 wherein the first and second thermal connector portions comprise complimentary portions of thermally conductive, solid, material that, when mated, provide a thermal pathway through the thermal connector.

11. An apparatus according to claim 8, wherein an evacuated connector enclosure is provided for housing the first thermal connector portion when connected to a second thermal connector portion.

12. An apparatus according to claim 1, wherein each of the one or more RF coil assemblies comprise a heat exchanger.

13. An apparatus according to claim 1, wherein the one or more RF coil assemblies comprise a thermal mass and at least one RF coil, the at least one RF coil being in thermal contact with the thermal mass.

14. An apparatus according to claim 1, wherein one or more of the RF coil assemblies comprise at least one RF coil and thermal insulation, the at least one RF coil being substantially thermally insulated from the surrounding environment by the thermal insulation.

15. An apparatus according to claim 1, wherein one or more of the RF coil assemblies comprise at least one RF coil and an outer housing that defines a sealed chamber in which a vacuum can be maintain, the at least one RF coil being located in the sealed chamber.

16. An apparatus according to claim 1, wherein the one or more RF coil assemblies are configured to stay below an operating temperature limit for at least 10 minutes after thermal separation from the cooler unit.

17. An apparatus according to claim 1, wherein the cooler unit comprises a cold head, wherein the separable thermal connection is provided between the cold head and the one or more coil assemblies.

18. An apparatus according to claim 1, wherein the one or more RF coil assemblies comprise at least one RF receive coil.

19. An apparatus according to claim 1, wherein the one or more RF coil assemblies comprise at least one RF transmit coil.

20. An apparatus according to claim 1, wherein the one or more RF coil assemblies comprise at least one RF coils tuned to the excitation frequency of Hydrogen, Carbon or Phosphorous nuclei.

21. An apparatus according to claim 1, wherein the one or more RF coil assemblies comprise RF coil tuning electronics.

22. An RF coil module for use with magnetic resonance apparatus, the RF coil module comprising at least one RF coil, wherein the RF coil module comprises the first part of a separable thermal connector that is releasably connectable to the second part of a separable thermal connector provided on an associated cooler unit.

23. A module according to claim 22 comprising a thermal mass, the thermal mass being in thermal contact with the at least one RF coil.

24. A cooler unit comprising a cooling source and at least one second part of a separable thermal connector, wherein the at least one second part of the separable thermal connector is releasable connectable to the first part of the thermal connector provided on a RF coil module.

25. A method of cooling RF coil assemblies comprising the steps of:
(i) taking one or more RF coil assemblies that each comprise at least one RF coil,
(ii) placing the one or more RF coil assemblies in thermal contact with a cooler unit to cool the RF coil assemblies, and
(iii) separating the one or more cooled RF coil assemblies from the cooler unit prior to use with magnetic resonance apparatus.
